(19) United States
(12) Patent Application Publication
(10) Pub. No.: US 2017/0155067 A1
(43) Pub. Date: Jun. 1, 2017

(54) METHOD OF MANUFACTURING SEMICONDUCTOR DEVICE AND SEMICONDUCTOR DEVICE

(71) Applicant: FUJIFILM CORPORATION, Tokyo (JP)

(72) Inventors: Yoshihisa USAMI, Kanagawa (JP); Kouki TAKAHASHI, Kanagawa (JP); Yoshiki MAEHARA, Kanagawa (JP); Seigo NAKAMURA, Kanagawa (JP)

(73) Assignee: FUJIFILM CORPORATION, Tokyo (JP)

(21) Appl. No.: 15/430,629

(22) Filed: Feb. 13, 2017

Related U.S. Application Data
(63) Continuation of application No. PCT/JP2015/073156, filed on Aug. 18, 2015.

(30) Foreign Application Priority Data
Sep. 18, 2014 (JP) 2014-190135

(51) Int. Cl. H01L 51/05; B23K 26/351

(52) U.S. Cl. CPC H01L 51/0512; B23K 26/351

(57) ABSTRACT

Disclosed are a manufacturing method capable of manufacturing a semiconductor device having a plurality of organic semiconductor elements with a simple process and high productivity, and a semiconductor device. This problem is solved by forming, on an insulating substrate, electrodes corresponding to a plurality of semiconductor elements, in which the position of an uppermost portion of each of a source electrode and a drain electrode is higher than that of a gate electrode, forming an organic semiconductor film on a surface of an insulating support, forming grooves in the organic semiconductor film to form divided regions according to the individual semiconductor elements, and aligning and laminating the insulating support and the insulating substrate.

### CROSS-REFERENCE TO RELATED APPLICATIONS

This application is a Continuation of PCT International Application No. PCT/JP2015/073156 filed on Aug. 18, 2015, which claims priority under 35 U.S.C. §119(a) to Japanese Patent Application No. 2014-190135 filed on Sep. 18, 2014. The above application is hereby expressly incorporated by reference, in its entirety, into the present application.

### BACKGROUND OF THE INVENTION

1. Field of the Invention

The present invention relates to a method of manufacturing a semiconductor device having a plurality of bottom gate-bottom contact organic semiconductor elements, and a semiconductor device manufactured by the manufacturing method.

2. Description of the Related Art

Various structures of an organic semiconductor element are known according to the positional relationship between a gate electrode, a source electrode, and a drain electrode and an organic semiconductor film. Representatively, four structures of a bottom gate-bottom contact type, a bottom gate-top contact type, a top gate-bottom contact type, and a top gate-top contact type are known.

Of these, a bottom gate-bottom contact type, in which a gate electrode is formed on an insulating substrate, an source electrode and a drain electrode are formed on an insulating film covering the gate electrode, and an organic semiconductor film is formed on the source electrode and the drain electrode, has an advantage in that a high temperature process or a solution process does not affect the organic semiconductor film.

In manufacturing a bottom gate-bottom contact organic semiconductor element, as an example, first, as shown in JP2007-96288A or JP2010-71906A, a gate electrode made of silver, gold, or the like is formed on an insulating substrate.

The gate electrode is formed by, for example, photolithography, in which a metal film to be a gate electrode is formed on the substrate, photoresist is patterned and formed on the metal film, unnecessary metal is removed by etching, and photoresist is removed.

Next, an insulating film (gate insulating film) made of silicon oxide, aluminum oxide, or the like is formed so as to cover the gate electrode.

The insulating film is formed by, for example, a vapor film deposition method, such as sputtering, chemical vapor deposition (CVD), or atomic layer deposition (ALD). Furthermore, a method is also known in which an organic material is coated or printed and hardened by light or heat to form a gate insulating film.

Next, a source electrode and a drain electrode are formed on the gate insulating film by the same method as the gate electrode.

An organic semiconductor film is patterned and formed on the source electrode and the drain electrode, thereby forming a bottom gate-bottom contact organic semiconductor element.

In this way, in the bottom gate-bottom contact organic semiconductor element, after the electrodes or the insulating film is formed by a high temperature process or a solution process, finally, the organic semiconductor film is formed.

For this reason, the characteristics of the organic semiconductor film are not deteriorated by the high temperature process or the solution process.

### SUMMARY OF THE INVENTION

On the other hand, a semiconductor device, such as an integrated circuit, is constituted by combining a plurality of semiconductor elements. Accordingly, in a semiconductor device having organic semiconductor elements, it is necessary to pattern and form an organic semiconductor film according to all organic semiconductor elements.

In an organic semiconductor element, an organic semiconductor film can be formed by photolithography or a printing method.

However, it is very challenging to form an organic semiconductor film at proper positions corresponding to all of a plurality of semiconductor elements, and it is difficult to improve productivity.

In addition, the organic semiconductor film is used in a state of polycrystal or single crystal. In general, single crystal is preferably used since there is less influence of electric charge movement inhibition in a crystal interface and mobility increases.

On the other hand, if the organic semiconductor film is formed on the source electrode and the drain electrode by photolithography or a printing method, crystallinity of the organic semiconductor film is degraded due to surface unevenness or a surface distribution with different surface energy. If crystal is produced on a solid surface, such as a source electrode or a drain electrode, the crystal array of the organic semiconductor is disordered under the influence of atoms on the solid surface having a cyclic array different from an organic semiconductor.

The invention has been accomplished in order to solve such problems in the related art, and an object of the invention is to provide a manufacturing method capable of manufacturing a semiconductor device having organic semiconductor elements made of an organic semiconductor film having satisfactory crystallinity with a simple process and high productivity in a semiconductor device having a plurality of bottom gate-bottom contact organic semiconductor elements, and a semiconductor device manufactured by the manufacturing method.

In order to attain such an object, a method of manufacturing a semiconductor device of the invention includes an electrode forming step of forming, on an insulating substrate, a combination of a gate electrode, a source electrode, and a drain electrode corresponding to a plurality of semiconductor elements, in which the position of an uppermost portion of each of the source electrode and the drain electrode is higher than that of the gate electrode, a film forming step of forming an organic semiconductor film on a surface of an insulating support, a patterning step of forming grooves in the organic semiconductor film to form divided regions divided corresponding to the individual semiconductor elements in the organic semiconductor film, and a laminating step of aligning and stacking the insulating support and the insulating substrate with the organic semiconductor film turning toward the insulating substrate.

In the method of manufacturing a semiconductor device of the invention, it is preferable that, in the patterning step, the forming of the grooves in the organic semiconductor film is performed by laser light.

It is preferable that, in the electrode forming step, an insulating film covering the gate electrode is formed after the gate electrode is formed, and the source electrode and the drain electrode are formed on the insulating film.

It is preferable that the laminating step is performed such that a space is formed below the organic semiconductor film between the source electrode and the drain electrode.

It is preferable that in the laminating step, the alignment of the insulating support and the insulating substrate is performed using alignment marks formed on the insulating support and the insulating substrate.

It is preferable that the alignment mark of the insulating substrate is formed of the same material as at least one of the gate electrode, the source electrode, or the drain electrode of at least one of the organic semiconductor elements.

A semiconductor device of the invention includes an insulating substrate, a combination of a gate electrode, a source electrode, and a drain electrode formed on the insulating substrate corresponding to a plurality of semiconductor elements, in which the position of an uppermost portion of each of the source electrode and the drain electrode is higher than that of the gate electrode, an insulating support, and an organic semiconductor film which is supported by the insulating support, is provided on the source electrode and the drain electrode, and is formed in regions corresponding to the plurality of semiconductor elements over the entire surface. The organic semiconductor film has a plurality of divided regions divided by grooves according to the individual semiconductor elements.

It is preferable that the semiconductor device of the invention further includes an insulating film covering the gate electrode, the source electrode and the drain electrode are formed on the insulating film.

It is preferable that each of the divided regions of the organic semiconductor film is in contact with only the source electrode and the drain electrode of the corresponding organic semiconductor element.

According to the invention, the insulating substrate, on which the electrodes constituting a plurality of organic semiconductor elements are formed, and the insulating support having the organic semiconductor film divided into a plurality of regions by the grooves are aligned and laminated, whereby it is possible to form an organic semiconductor film on a plurality of organic semiconductor elements at once, and to produce a semiconductor device having a plurality of organic semiconductor elements. The organic semiconductor elements of the semiconductor device have the organic semiconductor film having satisfactory crystallinity.

For this reason, according to the invention, it is possible to manufacture a semiconductor device having a plurality of organic semiconductor elements having high mobility simply and at low cost.

### BRIEF DESCRIPTION OF THE DRAWINGS

FIG. 1A is a schematic top view of an example of a semiconductor device of the invention, and FIG. 1B is a cross-sectional view taken along the line b-b of FIG. 1A.

FIG. 2A is a schematic top view illustrating an example of a method of manufacturing a semiconductor device of the invention, and FIG. 2B is a cross-sectional view taken along the line b-b of FIG. 2A.

FIG. 3A is a schematic top view illustrating an example of a method of manufacturing a semiconductor device of the invention, and FIG. 3B is a cross-sectional view taken along the line b-b of FIG. 3A.

FIG. 4A is a schematic top view illustrating an example of a method of manufacturing a semiconductor device of the invention, and FIG. 4B is a cross-sectional view taken along the line b-b of FIG. 4A.

FIG. 5 is another conceptual diagram showing an organic semiconductor element constituting the semiconductor device of the invention.

FIG. 6 is another conceptual diagram showing an organic semiconductor element constituting the semiconductor device of the invention.

### DESCRIPTION OF THE PREFERRED EMBODIMENTS

Hereinafter, a method of manufacturing a semiconductor device and a semiconductor device of the invention will be described in detail based on a suitable example shown in the accompanying drawings.

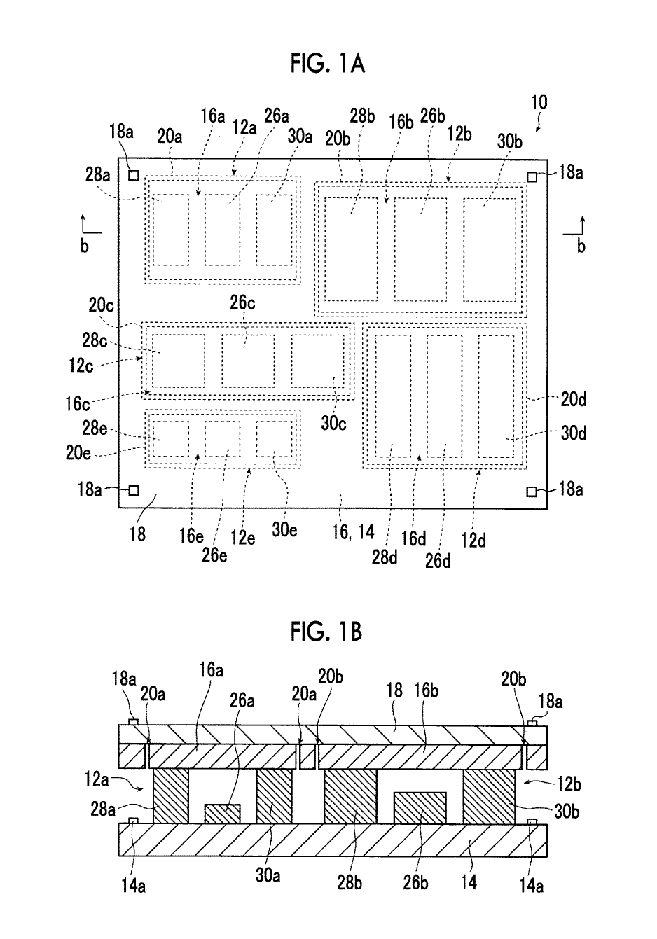

FIGS. 1A and 1B conceptually show an example of a semiconductor device of the invention manufactured by the method of manufacturing a semiconductor device of the invention. FIG. 1A is a top view, and FIG. 1B is a cross-sectional view taken along the line b-b of FIG. 1A.

A semiconductor device 10 of the illustrated example is a semiconductor device having five organic semiconductor elements 12a to 12e. Specifically, the semiconductor device 10 has an insulating substrate 14, the organic semiconductor elements 12a, 12b, 12c, 12d, and 12e, an organic semiconductor film 16, and an insulating support 18.

In the organic semiconductor film 16, divided regions 16a to 16e divided corresponding to the respective organic semiconductor elements by grooves 20a to 20e are formed. The divided regions 16a to 16e are divided by the grooves 20a to 20e in a state of being electrically insulated from the outside organic semiconductor film 16 in a surface direction.

In the semiconductor device 10 of the invention, for the insulating substrate 14, various sheet-like substances made of various materials used in a semiconductor device having organic semiconductor elements are available. In the following description, the “insulating substrate 14” is referred to as a “substrate 14”.

As the substrate 14, specifically, sheet-like substances (plate-like substances or films) made of ceramic, glass, plastic, or various insulating materials are illustrated. A sheet-like substance made of a conductor with an insulating layer formed on the surface thereof, such as a metal sheet with an insulating layer, such as an oxide layer, formed on the surface thereof, is also available as the substrate 14.

The substrate 14 may have a multilayer configuration, such as a configuration in which a plurality of sheet-like substances are laminated.

The thickness of the substrate 14 may be appropriately set to a thickness capable of supporting the entire semiconductor device 10 according to the forming material, the size of the semiconductor device 10, or the like.

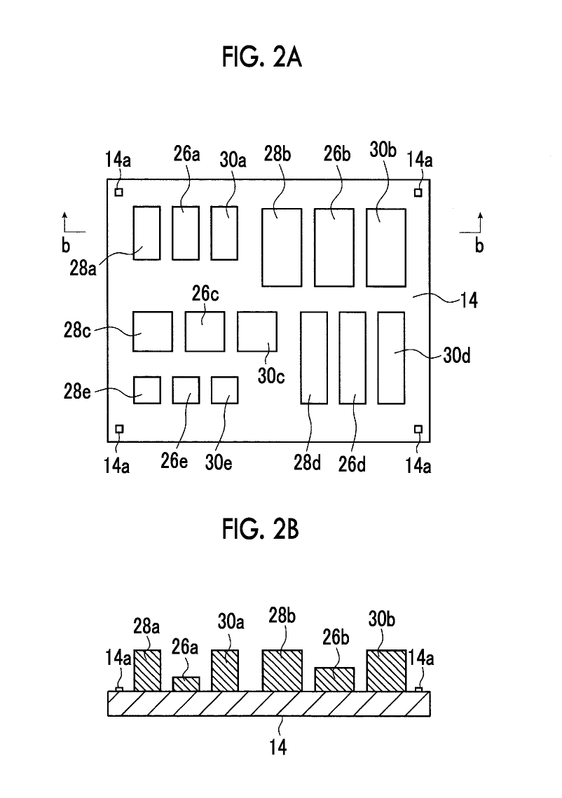

In the semiconductor device 10 of the illustrated example, alignment marks 14a for alignment with the insulating support 18 are formed at four corners on the surface of the substrate 14 (see FIG. 2A). The surface of the substrate 14 is, that is, a forming surface of the organic semiconductor elements.

For the alignment marks 14a, in addition to a square shape of the illustrated example, for example, various known marks used for alignment of two sheet-like substances, such as a cross shape, are available.

It is preferable that the alignment marks 14a are formed of the same material as at least one of a gate electrode, a source electrode, or a drain electrode of at least one of the organic semiconductor elements 12a, . . . , or 12e.

With this, it is possible to form the electrodes and the alignment marks 14a simultaneously. It is preferable in that it is possible to accurately ascertain the positional relationship between the electrodes and the alignment marks 14a, or the like.

The semiconductor device 10 has five organic semiconductor elements (organic thin film transistors) including the organic semiconductor elements 12a to 12e. For this reason, the electrodes constituting the organic semiconductor elements 12a to 12e are formed on the substrate 14.

Specifically, on the substrate 14, a gate electrode 26a, a source electrode 28a, and a drain electrode 30a constituting the organic semiconductor element 12a, a gate electrode 26b, a source electrode 28b, and a drain electrode 30b constituting the organic semiconductor element 12b, a gate electrode 26c, a source electrode 28c, and a drain electrode 30c constituting the organic semiconductor clement 12c, a gate electrode 26d, a source electrode 28d, and a drain electrode 30d constituting the organic semiconductor element 12d, and a gate electrode 26e, a source electrode 28e, and a drain electrode 30e constituting the organic semiconductor element 12e are formed.

In each of the organic semiconductor elements 12a to 12e, the gate electrode, the source electrode, and the drain electrode may be formed of various materials used for the gate electrode, the source electrode, and the drain electrode.

As an example, metal, such as silver, gold, aluminum, copper, platinum, lead, zinc, tin, or chromium, an alloy, transparent conductive oxide (TCO), such as indium tin oxide (ITO), a conductive polymer, such as polyethylenedioxythiophene-polystyrene sulfonate (PEDOT-PSS), a laminate structure thereof, or the like is illustrated.

In each of the organic semiconductor elements 12a to 12e, for the forming materials of the gate electrode, the source electrode, and the drain electrode, all electrodes may be farmed of the same material, or one or more electrodes may be farmed of a different material.

For the forming materials of the electrodes of the organic semiconductor elements 12a to 12e, the same material may be used in all elements or a different material may be used in one or more elements.

In the organic semiconductor elements constituting the semiconductor device 10 of the invention, the height, size, shape, or the like of each of the gate electrode, the source electrode, and the drain electrode may be appropriately set according to the purpose or the like of the semiconductor device 10 to be produced.

Though not shown, the organic semiconductor elements 12a to 12e are connected at least one of different organic semiconductor elements 12a, . . . , or 12e. In at least one of the organic semiconductor elements 12a, . . . , or 12e, interconnects for connection to an external device are provided.

These interconnects may be formed by known methods.

In the organic semiconductor elements 12a to 12e constituting the semiconductor device 10 of the invention, the height of an uppermost portion of each of the source electrode and the drain electrode is higher than that of the gate electrode.

That is, in the organic semiconductor element 12a, the uppermost portion of each of the source electrode 28a and the drain electrode 30a is higher than the uppermost portion of the gate electrode 26a. In the organic semiconductor element 12b, the uppermost portion of each of the source electrode 28b and the drain electrode 30b is higher than the uppermost portion of the gate electrode 26b. In the organic semiconductor element 12c, the uppermost portion of each of the source electrode 28c and the drain electrode 30c is higher than the uppermost portion of the gate electrode 26c, and in the organic semiconductor element 12d, the uppermost portion of each of the source electrode 28d and the drain electrode 30d is higher than the uppermost portion of the gate electrode 26d. In addition, in the organic semiconductor element 12e, the uppermost portion of each of the source electrode 28e and the drain electrode 30e is higher than the uppermost portion of the gate electrode 26e.

In the illustrated example, in all of the organic semiconductor elements 12a to 12e, the uppermost portions of the source electrode and the drain electrode have the same height.

The height of the electrode described herein is the height from the surface of the substrate 14 in a direction orthogonal to the substrate 14.

In the semiconductor device 10, the organic semiconductor elements 12a to 12e are constituted by providing the organic semiconductor film 16 supported by the insulating support 18 so as to be laminated on the source electrodes and the drain electrodes formed on the substrate 14.

Accordingly, the uppermost portion of each of the source electrode and the drain electrode is made higher than the uppermost portion of the gate electrode, whereby it is possible to provide a space between the gate electrode and the organic semiconductor film 16 and to insulate the gate electrode from the organic semiconductor film with the space. That is, even if an insulating film (gate insulating film) is not formed, it is possible to make the space between the gate electrode and the organic semiconductor film 16 act as an insulating film.

In the semiconductor device 10, the difference in height between the gate electrode and each of the source electrode and the drain electrode of each organic semiconductor element may be appropriately set to an amount of preventing the gate electrode and the organic semiconductor film 16 in each organic semiconductor element from being in contact with each other according to bending strength of insulating support 18, the width of the interval between the source electrode and the drain electrode, flexibility required for the semiconductor device 10, or the like.

According to the studies of the inventors, the difference in height between the gate electrode and each of the source electrode and the drain electrode is preferably 0.01 to 10 μm, more preferably, 0.1 to 2μm, and particularly preferably, 0.2 to 1 μm.

If the difference in height between the gate electrode and each of the source electrode and the drain electrode is set to be equal to or greater than 0.01 μm, it is preferable in that it is possible to suitably prevent the contact of the gate electrode and the organic semiconductor film 16, to secure sufficient insulation, or the like.

If the difference in height between the gate electrode and each of the source electrode and the drain electrode is set to be equal to or less than 10 μm, it is preferable in that it is possible to lower an applied voltage, to obtain a thin semiconductor device, or the like.

In the semiconductor device 10 of the illustrated example, all of the organic semiconductor elements 12a to 12e are subject to adjustment of the height of the electrode such that the height of the uppermost portion of each of the source electrode and the drain electrode is made higher than that of the gate electrode.

In the invention, as a method of making the height of the uppermost portion of each of the source electrode and the drain electrode higher than that of the gate electrode, various methods are available. For example, the height of the uppermost portion of each of the source electrode and the drain electrode may be made higher than that of the gate electrode by providing a mount on the surface of the substrate 14, forming the gate electrode on the surface of the substrate 14, and forming the source electrode and the drain electrode on the mount.

The organic semiconductor film 16 is provided so as to be laminated on the source electrode and the drain electrode of each of the organic semiconductor elements 12a to 12e. The organic semiconductor film 16 is supported by the insulating support 18.

The organic semiconductor film 16 is a layer made of an organic semiconductor film material.

In the invention, as the organic semiconductor film material, various known material used for an organic semiconductor film in an organic semiconductor element are available.

Specifically, pentacene derivatives, such as 6,13-bis(triisopropylsilylethynyl)pentacene (TIPS pentacene), anthradithiophene derivatives, such as 5,11-bis(triethylsilylethynyl)anthradithiophene (TES-ADT), benzodithiophene (BDT) derivatives, benzothienobenzothiophene (BTBT) derivatives, such as dioctylbenzothienobenzothiophene (C 8 -BTBT), dinaphthothienothiophene (DNTT) derivatives, dinaphthobenzodithiophene (DNBDT) derivatives, 6,12-dioxaanthanthrene(perixanthenoxanthene) derivatives, naphthalenetetracarboxdiimide (NTCDI) derivatives, perylenetetracarboxdiimide (PTCDI) devivatives, polythiophene derivatives, poly(2,5-bis(thiophene-2-yl)thieno [3,2-b]thiophene) (PBTTT) derivatives, tetracyanoquinodimethane (TCNQ) derivatives, oligothiophenes, phthalocyanines, fullerenes, or the like are illustrated.

The organic semiconductor film 16 may be polycrystal or single crystal, and is preferably in a state of single crystal in that there is less influence of electric charge movement inhibition in a crystal interface, mobility increases, or the like.

In the invention, for the organic semiconductor film 16, since the organic semiconductor film 16 is formed on the surface of the planar insulating support 18, the organic semiconductor film 16 in a state of single crystal is easily formed.

In the semiconductor device 10 of the invention, the thickness of the organic semiconductor film 16 may be appropriately set according to the purpose of the semiconductor device 10 to be produced, the shape or configuration of the organic semiconductor element, or the like.

In the organic semiconductor film 16, a plurality of divided regions 16a to 16e divided according to the individual organic semiconductor elements constituting the semiconductor device 10 by the grooves 20a to 20e reaching the insulating support 18 are formed.

Specifically, the divided region 16a divided by the groove 20a corresponds to the organic semiconductor element 12a. The divided region 16a of the organic semiconductor film 16 is provided to be laminated on the top surfaces of the source electrode 28a and the drain electrode 30a of the organic semiconductor element 12a, whereby the bottom gate-bottom contact organic semiconductor element 12a is formed.

The divided region 16b divided by the groove 20b corresponds to the organic semiconductor element 12b. The divided region 16b of the organic semiconductor film 16 is provided to be laminated on the top surfaces of the source electrode 28b and the drain electrode 30b of the organic semiconductor element 12b, whereby the bottom gate-bottom contact organic semiconductor element 12b is formed.

The divided region 16c divided by the groove 20c corresponds to the organic semiconductor element 12c. The divided region 16c of the organic semiconductor film 16 is provided to be laminated on the top surfaces of the source electrode 28c and the drain electrode 30c of the organic semiconductor element 12c, whereby the bottom gate-bottom contact organic semiconductor element 12c is formed.

The divided region 16d divided by the groove 20d corresponds to the organic semiconductor element 12d. The divided region 16d of the organic semiconductor film 16 is provided to be laminated on the top surfaces of the source electrode 28d and the drain electrode 30d of the organic semiconductor element 12d, whereby the bottom gate-bottom contact organic semiconductor clement 12d is formed.

In addition, the divided region 16e divided by the groove 20e corresponds to the organic semiconductor element 12e. The divided region 16e of the organic semiconductor film 16 is provided to be laminated on the top surface of the source electrode 28e and the drain electrode 30e of the organic semiconductor element 12e, whereby the bottom gate-bottom contact organic semiconductor element 12e is formed.

The grooves 20a to 20e have a depth to each the insulating support 18 over the entire region. Accordingly, the divided regions 16a to 16e are electrically insulated from the outside organic semiconductor film 16 in the surface direction thereof

As described above, in the invention, since the source electrode and the drain electrode are higher than the gate electrode, in the organic semiconductor elements 12a to 12e, the organic semiconductor film 16 is not in contact with the gate electrode.

In the semiconductor device 10 of the invention, the size or shape of each of the divided regions 16a to 16e constituting the organic semiconductor elements 12a to 12e may be appropriately set according to the purpose of the semiconductor device 10 to be produced, the shape or configuration of each of the organic semiconductor elements 12a to 12e, or the like.

As the shape of each of the divided regions 16a to 16e, in addition to the square shape of the illustrated example, various shapes, such as a circular shape, an elliptical shape, a polygonal shape, and an undefined shape, are available according to the shape or configuration of the organic semiconductor element, the shape, size, or position of each of the organic semiconductor elements 12a to 12e in the semiconductor device 10, or the like.

The width of each of the grooves 20a to 20e may be appropriately set to a width capable of electrically insulating the divided regions 16a to 16e from the outside organic semiconductor film 16 according to the thickness of the organic semiconductor film 16, or the like.

As described above, the organic semiconductor film 16 is supported by the insulating support 18. In the following description, the “insulating support 18” is referred to as a “support 18”.

For the support 18, various sheet-like substances are available as long as these are insulation and can support the organic semiconductor film 16.

It is preferable that the support 18 has a property hard to pass gas or moisture therethrough and has a linear expansion coefficient close to an organic semiconductor. Taking this into consideration, as the support 18, a sheet-like substance (organic film) made of an organic material, such as polyethylene terephthalate (PET), polyethylene naphthalate (PEN), cycloolefin copolymer (COC), cycloolefin polymer (COP), or a liquid crystal film, or a sheet-like substance made of glass is preferably used. Of these, a sheet-like substance made of PET, PEN, COC, or COP is suitably used.

The thickness of the support 18 may be appropriately set to a thickness capable of supporting the organic semiconductor film 16 according to the size of the semiconductor device 10, the forming material of the support 18, or the like.

In the semiconductor device 10 of the illustrated example, although the substrate 14 and the support 18 have the same size and shape, the substrate 14 and the support 18 may be different in size and/or shape.

In the support 18, alignment marks 18a for alignment with the substrate 14, on which the electrodes of the organic semiconductor elements are formed, are formed.

In the illustrated example, in the support 18, four alignment marks 18a are formed so as to completely overlap the four alignment marks 14a formed on the substrate 14 in the surface direction of the substrate 14 and the support 18.

Accordingly, the positions of the electrodes constituting the respective organic semiconductor elements are set according to the alignment marks 14a on the substrate 14, and the positions of the grooves 20a to 20e forming the divided regions 16a to 16e are set by the alignment marks 18a on the support 18, whereby it is possible to align the source electrodes and the drain electrodes with the corresponding divided regions 16a to 16e in the organic semiconductor elements 12a to 12e.

In the invention, in addition to forming the alignment marks so as to completely overlap each other in the surface direction on the substrate 14 and the support 18, various methods which can align the positions of two sheet-like substances in the surface direction with each other are available.

As the shapes of the alignment marks 18a, in addition to the square shape of the illustrated example, various shapes are available. The alignment marks having different shapes may be used on the substrate 14 and the support 18.

Hereinafter, the invention will be described in more detail by describing the method of manufacturing the semiconductor device 10 referring to the conceptual diagrams of FIGS. 2A, 2B, 3A, 3B, 4A, and 4B.

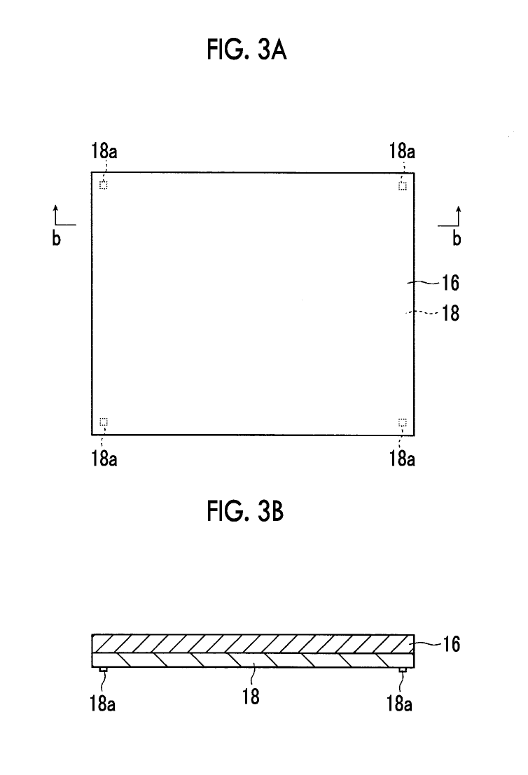

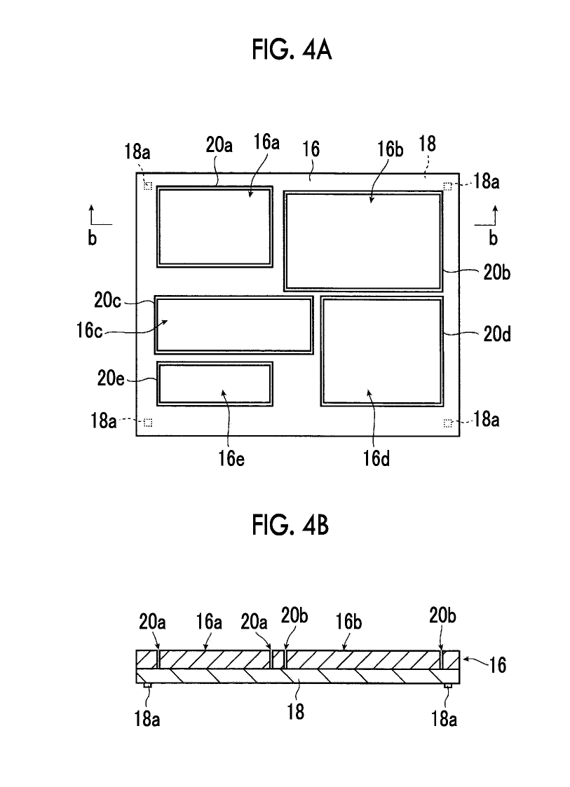

FIG. 2A is a top view similar to FIG. 1A, and FIGS. 3A and 4A are bottom views in which the front and rear are reversed. All of FIGS. 2B, 3B, and 4B are cross-sectional views taken along the line b-b of FIGS. 2A, 3A, and 4A.

First, as shown in FIGS. 2A and 2B, the electrodes constituting the organic semiconductor elements 12a to 12e are formed on the surface of the square substrate 14.

That is, in the illustrated example, on the surface of the substrate 14, the gate electrode 26a, the source electrode 28a, and the drain electrode 30a forming the organic semiconductor element 12a, the gate electrode 26b, the source electrode 28b, and the drain electrode 30b forming the organic semiconductor element 12b, the gate electrode 26c, the source electrode 28c, and the drain electrode 30c forming the organic semiconductor element 12c, the gate electrode 26d, the source electrode 28d, and the drain electrode 30d forming the organic semiconductor element 12d, and the gate electrode 26e, the source electrode 28e, and the drain electrode 30e forming the organic semiconductor element 12e are formed.

As a method of forming the gate electrode, the source electrode, and the drain electrode, various known methods according to the forming materials are available.

As an example, a method using a vapor film deposition method (vapor deposition method), such as sputtering or vacuum deposition, and photolithography, a method using a vapor film deposition method and a mask covering non-film forming portions, a method by printing, such as screen printing or ink jet, or the like is illustrated.

In the organic semiconductor elements 12a to 12e, for the gate electrode, the source electrode, and the drain electrode, all electrodes may be formed simultaneously, or one electrode and/or two electrodes may be formed sequentially.

For the electrodes of the organic semiconductor elements 12a to 12e, the electrodes of all elements may be formed simultaneously or the electrodes of one element and/or the electrodes of a plurality of elements may be formed sequentially.

In a case of forming the gate electrode and the source electrode and/or the drain electrode simultaneously, as a method of making the height of the source electrode or the drain electrode higher than that of the gate electrode, known methods may be used. For example, in a case of forming the electrodes using screen printing, a mesh size is adjusted, thereby adjusting the height of the electrode. Furthermore, in a case of forming the electrodes using ink jet, the number of droplets of ink is adjusted, thereby adjusting the height of the electrode.

Preferably, the alignment marks 14a are formed at the four corners of the substrate 14 simultaneously with forming at least one of the gate electrode, the source electrode, or the drain electrode.

With this, it is possible to accurately ascertain the positional relationship between the alignment marks 14a and the source electrodes and the drain electrodes of the respective organic semiconductor elements 12a to 12e, thereby more accurately determining the forming positions of the grooves 20a to 20e described below.

In a case of forming the electrodes sequentially, it is preferable that the alignment marks 14a are formed simultaneously with the electrode which is first formed. With this, it is possible to form the subsequent electrodes by performing alignment using the alignment marks 14a with respect to the electrode which is first formed.

As described above, though not shown, after the gate electrodes, the source electrodes, and the drain electrodes of all of the organic semiconductor elements 12a to 12e are formed, wirings for connection of the organic semiconductor elements 12a to 12e are formed according to the semiconductor device 10 to be produced.

On the other hand, as shown in FIGS. 3A and 3B, the organic semiconductor film 16 made of an organic semiconductor material is formed on one surface of the square support 18.

The organic semiconductor film 16 can be formed using known film forming techniques according to the organic semiconductor materials to be used.

As a suitable example, forming using a so-called coating method, in which a coating liquid (coating material) in which an organic semiconductor material to be the organic semiconductor film 16 is dissolved in a solvent is prepared and the coating material is coated on the support 18 and dried is illustrated. At this time, as a coating method of the coating material, various known coating methods, such as spin coating, drop casting, dip coating, doctor knife coating, and gravure coating, are available.

In addition, a vapor film deposition method, such as vacuum deposition, or a method, such as printing, is suitably available for forming the organic semiconductor film 16.

The organic semiconductor film 16 may be formed on the entire surface of the support 18, or may be formed corresponding to the regions for forming the organic semiconductor elements 12a to 12e over the entire surface, excluding the peripheral portion of the support 18.

As described above, the organic semiconductor film 16 is preferably in a state of crystal, such as single crystal or polycrystal, and particular preferably, in a state of single crystal. The organic semiconductor film 16 is in a state of single crystal, whereby it is possible to manufacture an organic semiconductor element with high mobility.

As a method of crystallizing the organic semiconductor film 16, various known crystallizing method are available. Specifically, a method of heating the formed organic semiconductor film 16. a method of driving the film from the end of the coated film when forming the organic semiconductor film 16 using a coating method, or the like is illustrated.

In addition, the alignment marks 18a are formed at the four corners of the surface opposite to the forming surface of the organic semiconductor film 16 of the support 18. As described above, in the illustrated example, the alignment marks 18a are formed at the positions overlapping the alignment marks 14a formed on the substrate 14 in the surface direction.

A method of forming the alignment marks 18a on the support 18, various known methods which form marks for alignment in the surface direction on a sheet-like substance are available according to the forming materials of the support 18, or the like.

After the organic semiconductor film 16 is formed on the support 18, as shown in FIGS. 4A and 4B, the grooves reaching the support 18 are formed in the organic semiconductor film 16 to form the divided regions 16a to 16e divided corresponding to the individual organic semiconductor elements 12a to 12e in the organic semiconductor film 16.

Specifically, the groove 20a is formed at a position corresponding to the organic semiconductor element 12a to define the divided region 16a electrically insulated from the outside organic semiconductor film 16. The groove 20b is formed at a position corresponding to the organic semiconductor element 12b to define the divided region 16b electrically insulated from the outside organic semiconductor film 16. The groove 20c is formed at a position corresponding to the organic semiconductor element 12c to define the divided region 16c electrically insulated from the outside organic semiconductor film 16. The groove 20d is formed at a position corresponding to the organic semiconductor element 12d to define the divided region 16d electrically insulated from the outside organic semiconductor film 16. In addition, the groove 20e is formed at a position corresponding to the organic semiconductor element 12e to define the divided region 16e electrically insulated from the outside organic semiconductor film 16.

It is preferable that the grooves 20a to 20e are aligned and formed using the alignment marks 18a. With this, it is possible to appropriately align the source electrodes and the drain electrodes of the organic semiconductor elements 12a to 12e with the individual divided regions 16a to 16e of the organic semiconductor film 16.

As a method of forming the grooves 20a to 20e, various methods are available.

As a preferable method, laser patterning in which the positions of the organic semiconductor film 16 where the grooves 20a to 20e are formed are irradiated with laser light and the organic semiconductor film 16 is removed by ablation, sublimation, evaporation, or the like is illustrated. As a method of laser patterning, various known methods, such as a method using laser beam scanning, a method of reducing and projecting laser light corresponding to the grooves 20a to 20e like a stepper, and a method of applying laser light corresponding to the grooves 20a to 20e using a light shielding mask, are available.

As a method of forming the grooves 20a to 20e, in addition, various methods, such as a method using mechanical processing and a method using photolithography, are available.

In this way, after the substrate 14, on which the gate electrodes, the source electrodes, and the drain electrodes of the organic semiconductor elements 12a to 12e are formed, and the support 18, on which the organic semiconductor film 16 having the grooves 20a to 20e is formed, are produced, the substrate 14 and the support 18 are aligned using the alignment marks 14a and the alignment marks 18a, thereby laminating the organic semiconductor film 16 on the source electrodes and the drain electrodes.

With this, as shown in FIGS. 1A and 1B, the semiconductor device 10 having the five bottom gate-bottom contact organic semiconductor elements 12a to 12e is produced.

Fixing of the substrate 14 to the support 18 may be performed using known methods, such as a method using a known jig for fixing two plate-like substances. Fixing of the substrate 14 to the support 18 is, that is, fixing of the source electrodes and the drain electrodes to the organic semiconductor film 16.

As will be apparent from the above description, according to the invention, it is possible to form the organic semiconductor film on a plurality of organic semiconductor elements only by aligning and laminating the substrate 14, on which the electrodes corresponding to a plurality of organic semiconductor elements are formed, and the support 18, on which the organic semiconductor film 16 having the regions divided corresponding to a plurality of organic semiconductor elements is formed.

The organic semiconductor film corresponding to each of a plurality of organic semiconductor elements can be produced by forming the organic semiconductor film 16 in the forming regions of the organic semiconductor elements over the entire surface and forming the grooves in the organic semiconductor film. Therefore, according to the invention, a semiconductor device having a plurality of organic semiconductor elements is obtained simply and at low cost.

In addition, since the organic semiconductor film is formed on the planar support, not on the substrate having unevenness with the electrode formed thereon, the organic semiconductor film can be formed in the form of a crystal film having a large domain, preferably, a single crystal film, whereby it is possible to increase mobility of the individual organic semiconductor elements.

Those skilled in the art will not reach such a configuration in which the substrate 14 with the electrodes corresponding to a plurality of organic semiconductor elements formed thereon and the support 18 having the organic semiconductor film 16 divided corresponding to a plurality of organic semiconductor elements are used and laminated.

This is because such a configuration may have a disadvantage that the substrate 14 and the support 18 are used, that is, two substrates are required, and accordingly, the number of parts increases or extra alignment is required.

However, the invention can obtain a remarkable effect that, as a result of forming the organic semiconductor film 16 on the support 18 separately and laminating the support 18, in a semiconductor device having a plurality of organic semiconductor elements, it is possible to form the organic semiconductor layers of all organic semiconductor elements simultaneously and simply, and it is possible to prevent the organic semiconductor layers corresponding to all organic semiconductor elements of the semiconductor device from being deteriorated due to other processes.

In a case of forming and then cutting organic semiconductor elements and giving insulation, it is necessary to remove an unnecessary organic semiconductor film by photolithography or laser. At this time, if an organic semiconductor film is formed on a substrate having unevenness, an unremoved portion is generated, in particular, in an end portion of an uneven portion, and as a result, insulation performance is deteriorated. In addition, if an organic semiconductor is formed on a substrate having unevenness, the film thickness of the organic semiconductor is different in a recess portion and a projection portion, and the characteristics of the organic semiconductor elements vary.

In contrast, in the invention, as described above, since the organic semiconductor film is formed on the planar support, in addition to an effect of form an organic semiconductor film having a large domain, and preferably, in a state of single crystal, it is possible to prevent a problem of degradation of insulation performance due to a removed portion of an organic semiconductor, or a problem of variation in characteristics of organic semiconductor elements due to variation in film thickness of an organic semiconductor.

In the semiconductor device 10, as shown in FIG. 1B, although a space is provided between the gate electrode of each of the organic semiconductor elements 12a to 12e and the organic semiconductor film 16, the space may be air, or may be filled with gas, such as nitrogen or argon.

Alternatively, the space may be filled with a liquid, such as water or a solvent, instead of gas.

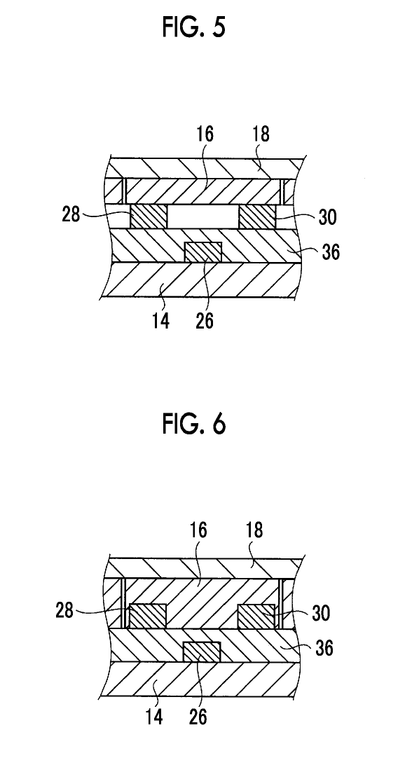

In the invention, as conceptually shown in FIG. 5, an organic semiconductor element may have a configuration in which a (gate) insulating film 36 covering a gate electrode 26 is formed on the substrate 14, a source electrode 28 and a drain electrode 30 are formed on the insulating film 36, and the organic semiconductor film 16 is provided so as to be laminated on the source electrode 28 and the drain electrode 30.

The insulating film 36 is provided, whereby it is possible to easily make the source electrode 28 and the drain electrode 30 higher than the gate electrode 26, and to more reliably insulate the gate electrode 26 from the organic semiconductor film 16. In addition, the insulating film 36 is provided, whereby it is possible to more reliably prevent the contact of the gate electrode 26 and the organic semiconductor film 16 or the contact of the gate electrode 26 and the source electrode 28 or the drain electrode 30 in a case where the semiconductor device is curved, or the like.

As a forming material of the insulating film 36, various known substances used as an insulating film in an organic semiconductor element are available.

As an example, synthetic resin, such as polyethylene, polyvinyl chloride, polyester, epoxy resin, melamine resin, phenol resin, or polyurethane, an organic insulator, such as natural rubber, cotton, or paper, metal oxide, such as silicon oxide (SiOₓ), magnesium oxide, aluminum oxide, titanium oxide, germanium oxide, yttrium oxide, zirconium oxide, niobium oxide, or tantalum oxide, metal nitride, such as silicon nitride (SiNₓ), metal nitroxide (metal oxynitride), such as silicon nitroxide (SiOₓN_{y}), an inorganic material, such as diamond-like carbon (DLC), various polymer materials, a laminate structure thereof, and the like are illustrated.

As a method of forming the insulating film 36, various known methods according to materials are available.

As an example, various physical vapor film deposition method (PVD), such as sputtering, vacuum deposition, and ion plating, various chemical vapor film deposition methods (CVD) including an atomic layer deposition method (ALD method or ALE method), a coating method, a printing method, a transfer method, and the like are illustrated.

In the invention, as conceptually shown in FIG. 6, an organic semiconductor element may have a configuration in which the organic semiconductor film 16 and the insulating film 36 are in contact with each other, for example, by pressing or the like.

However, the insulating film 36 may have a substance or a structure which inhibits electric charge movement. For this reason, if the organic semiconductor film 16 and the insulating film 36 are in contact with each other, mobility may be degraded due to the contact. In a case of forming the organic semiconductor film 16 using a coating method, if the organic semiconductor film 16 and the insulating film 36 are in contact with each other, crystal may be disordered due to the surface shape or substance of the insulating film 36, and mobility may be degraded.

Accordingly, in the invention, as shown in FIG. 1B or 5, it is preferable that the organic semiconductor film 16 of the divided region constituting each organic semiconductor element is in contact with only the source electrode and the drain electrode of the corresponding organic semiconductor element, and a space is provided below the organic semiconductor film 16. That is, the space is provided below the organic semiconductor film 16, whereby it is possible to prevent the contact of the organic semiconductor film 16 and the insulating film 36, and thus, to suppress the respective problems described above. If the organic semiconductor film 16 is formed directly on the insulating film 36, disorder of a crystal structure or a defect called trap occurs near an interface, and electric charge movement is inhibited. The space is provided below the organic semiconductor film 16, whereby it is possible to suppress such problems. In addition, the space is provided below the organic semiconductor film 16, it is possible to prevent separation of the interface between the insulating film and the organic semiconductor occurring when an element is bent.

Specifically, preferably, a space of 0.01 to 10 μm in the height direction of the electrode is provided, more preferably, a space of 0.1 to 2 μm is provided, and particularly preferably, a space of 0.1 to 1 μm is provided.

It is preferable that the space of each divided region below the organic semiconductor film 16 is set to be equal to or greater than 0.01 μm in that it is possible to suppress disorder of a crystal structure or trap, to suitably prevent the contact of the organic semiconductor film 16 and other members, to secure sufficient insulation, or the like.

It is preferable that the space of each divided region below the organic semiconductor film 16 is set to be equal to or less than 10 μm in that it is possible to lower an applied voltage, to obtain a thin semiconductor device, or the like.

Although the method of manufacturing a semiconductor device and the semiconductor device of the invention have been described above in detail, the invention is not limited to the above-described examples, and various improvements or alterations may be of course made without departing from the spirit and scope of the invention.

The invention is suitably available for manufacturing a semiconductor device having a plurality of organic TFTs, such as a liquid crystal display.

### EXPLANATION OF REFERENCES

10: semiconductor device
12a, 12b, 12c, 12d, 12e: organic semiconductor element
14: (insulating) substrate
14a, 18a: alignment mark
16: organic semiconductor film
16a, 16b, 16c, 16d, 16e: divided region
18: (insulating) support
20a, 20b, 20c, 20d, 20e: groove
26a, 26b, 26c, 26d, 26e: gate electrode
28a, 28b, 28c, 28d, 28e: source electrode
30a, 30b, 30c, 30d, 30e: drain electrode
36: insulating film

What is claimed is:

1. A method of manufacturing a semiconductor device, the method comprising:
an electrode forming step of forming, on an insulating substrate, a combination of a gate electrode, a source electrode, and a drain electrode corresponding to a plurality of semiconductor elements, in which the position of an uppermost portion of each of the source electrode and the drain electrode is higher than that of the gate electrode;
a film forming step of forming an organic semiconductor film on a surface of an insulating support;
a patterning step of forming grooves in the organic semiconductor film to form divided regions divided corresponding to the individual semiconductor elements in the organic semiconductor film; and
a laminating step of aligning and stacking the insulating support and the insulating substrate with the organic semiconductor film turning toward the insulating substrate.

2. The method of manufacturing a semiconductor device according to claim 1,
wherein, in the patterning step, the forming of the grooves in the organic semiconductor film is performed by laser light.

3. The method of manufacturing a semiconductor device according to claim 1,
wherein, in the electrode forming step, an insulating film covering the gate electrode is formed after the gate electrode is formed, and the source electrode and the drain electrode are formed on the insulating film.

4. The method of manufacturing a semiconductor device according to claim 1,
wherein the laminating step is performed such that a space is formed below the organic semiconductor film between the source electrode and the drain electrode.

5. The method of manufacturing a semiconductor device according to claim 1,
wherein, in the laminating step, the alignment of the insulating support and the insulating substrate is performed using alignment marks formed on the insulating support and the insulating substrate.

6. The method of manufacturing a semiconductor device according to claim 1,
wherein the alignment mark of the insulating substrate is formed of the same material as at least one of the gate electrode, the source electrode, or the drain electrode of at least one of the organic semiconductor elements.

7. A semiconductor device comprising:
an insulating substrate;
a combination of a gate electrode, a source electrode, and a drain electrode formed on the insulating substrate corresponding to a plurality of semiconductor elements, in which the position of an uppermost portion of each of the source electrode and the drain electrode is higher than that of the gate electrode;
an insulating support; and
an organic semiconductor film which is supported by the insulating support, is provided on the source electrode and the drain electrode, and is formed in regions corresponding to the plurality of semiconductor elements over the entire surface,
wherein the organic semiconductor film has a plurality of divided regions divided by grooves according to the individual semiconductor elements.

8. The semiconductor device according to claim 7, further comprising:
an insulating film covering the gate electrode,
wherein the source electrode and the drain electrode are formed on the insulating film.

9. The semiconductor device according to claim 7,
wherein each of the divided regions of the organic semiconductor film is in contact with only the source electrode and the drain electrode of the corresponding organic semiconductor element.
